(19) United States
(12) Patent Application Publication
(10) Pub. No.: US 2010/0006144 A1
(43) Pub. Date: Jan. 14, 2010

(54) PLASMON-ENHANCED PHOTO VOLTAIC CELL

(76) Inventors: Jeremy John Baumberg, Southampton (GB); Mamdouth Abdelsalam, Southampton (GB); Philip Nigel Bartlett, Southampton (GB)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 12/375,039

(22) PCT Filed: Jul. 23, 2007
(86) PCT No.: PCT/GB2007/002782

§ 371 Date: May 27, 2009

(30) Foreign Application Priority Data
Jul. 27, 2006 (GB) 0614891.0

(51) Int. Cl. H01L 31/108; H01L 31/18

(52) U.S. Cl. 136/255; 438/92; 257/E21.295; 257/E31.065

(57) ABSTRACT

A photovoltaic device and a method of making the photovoltaic device. The device includes a metallic surface defining a plurality of voids for confining surface plasmons. The metallic surface is coated with a semiconductor to form a Schottky region at an interface between the metallic surface and the semiconductor within each void.

### BACKGROUND OF THE INVENTION

The invention relates to photovoltaic cells. In particular, this invention relates to a plasmon-enhanced photovoltaic cell.

Photovoltaic technology struggles to deliver high efficiency yet cheap modules. Conventional silicon units reach 30% efficiencies and last for over 25 years but are expensive, while organic photovoltaics are having problems both with efficiencies below 10% and sensitivity to oxygen which reduces lifetimes below 5 years. Defects in semiconductors trap carriers reducing efficiencies, but high quality material is expensive to make.

### SUMMARY OF THE INVENTION

Aspects of the invention are defined in the accompanying claims.

According to an aspect of the invention there is provided a photovoltaic device comprising a metallic surface defining a plurality of voids for confining surface plasmons, wherein the metallic surface is coated with a semiconductor to form a Schottky region at an interface between the metallic surface and the semiconductor within each void.

According to another aspect of the invention there is provided a method of making a photovoltaic device, the method comprising: forming a metallic surface to define a plurality of voids for confining surface plasmons; and coating the metallic surface with a semiconductor to form a Schottky region at an interface between the metallic surface and the semiconductor within each void.

According to an embodiment of the invention, confinement of surface plasmons within the voids produces a high optical intensity in the Schottky region, which enhances electron-hole production in the semiconductor, and electron hole separation. Accordingly, a photovoltaic device with a high efficiency can be provided.

In accordance with an embodiment of the invention, the voids can be of a scale larger than 50 nm. For example, a largest dimension of the void (e.g. the diameter of a substantially spherical void or the square aperture of a pyramidal void) can be larger than 50 nm. Voids on this scale are more easily reproducible than smaller voids (e.g. of the scale 1 to 5 nm), making the manufacture process more reliable. This is a significant benefit in devices incorporating a large number of voids.

The voids can be pyramidal pits. A square aperture of the pyramidal pits can be in the range 400-2000 nm. More particularly, a square aperture of the pyramidal pits can be in the range 400-700 nm. In an alternative embodiment, the voids can be substantially spherical in shape. It is also envisaged that the voids can include other void-like shapes that are partially enclosed.

An ohmic top contact can be provided on the semiconductor. Alternatively, a Schottky top contact can be provided on the semiconductor.

The semiconductor can comprise an n-type semiconductor, such as n-doped CdTe, ZnO or PbTe. The semiconductor can comprise a p-type semiconductor, such as GaAs or InAs. The semiconductor can also comprise an alloy or heterostructure of these materials.

The metallic surface can be defined by a thin film metallic layer on a substrate. The metallic surface can deposited on the substrate. The substrate can be provided with a pattern that corresponds to the voids, whereby the deposited metal forms the metallic surface defining the voids.

The depletion length of the Schottky region can be selected to match an absorption length of light that is resonantly-tuned to a bandgap of the semiconductor. The depletion length can be in the range 100-1000 nm. The depletion length can be in the range 30-2000 nm.

The metallic surface can be folded to form a plurality of opposing faces. The voids defined in at least one of the faces can be larger than the voids defined in at least one other face. The metallic surface defining the voids in at least one of the faces can be coated with a different semiconductor to the metallic surface defining the voids in at least one other of the faces.

A plurality of quantum dots can be formed on the metallic surface prior to coating the metallic surface with the semiconductor.

According to a further aspect of the invention, there is provided a solar cell that includes a photovoltaic device of the kind described above.

### BRIEF DESCRIPTION OF THE DRAWINGS

For a better understanding of the invention and to show how the same may be carried into effect reference is now made by way of example to the accompanying drawings in which:

FIG. 1 shows an energy band diagram in accordance with an embodiment of the invention;

FIG. 2 shows a plot of reflectivity as a function of wavelength for pyramidal voids, in accordance with an embodiment of the invention;

FIGS. 3 to 5 show examples of photovoltaic devices in accordance with an embodiment of the invention;

FIG. 6(a) shows a photovoltaic device according to an embodiment of the invention, while FIG. 6(b) shows the band gap alignment and plasmon mode overlap for the example device shown in FIG. 6(a);

FIGS. 7(a)-7(c) show examples of fabrication methods in accordance with an embodiment of the invention; and

FIG. 8 shows an example of voids produced using the method described in relation to FIG. 7(c), in accordance with an embodiment of the invention.

### DETAILED DESCRIPTION

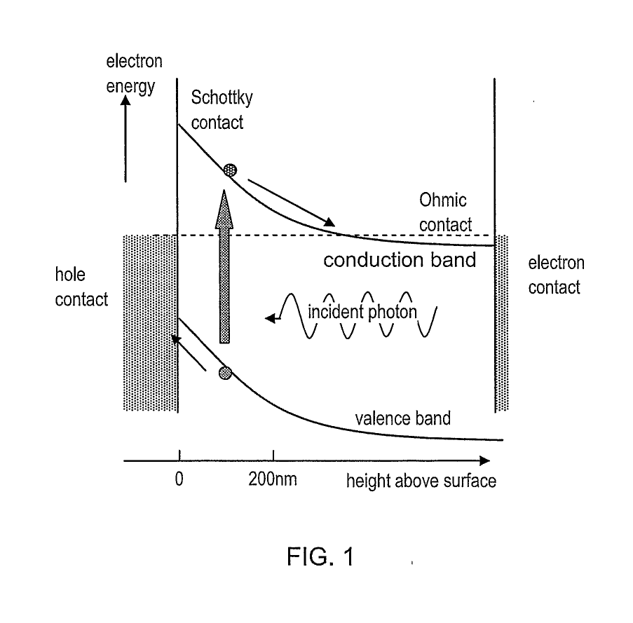

The novel feature of the solar cell in this patent is the metallic void geometry which is coated with the active absorbing layer embedded in a semiconductor and a top contact. The interface between the doped semiconductor and metal forms a high electric field (Schottky) region (FIG. 1). However normally, because of the interference between incident and reflected light rays, there would be no optical intensity within this high electric field region above a metal. In our structures, the nanostructure plasmon geometry allows strong optical intensity at the surface of the metal, thus generating electron-hole pairs in the place where they can be most easily separated and transported into the contacts.

Unlike a Grätzel electrochemical cell, this device needs no ion transport layers, but uses the heavily doped as-grown semiconductor to transport electrons to the top contact—this is likely to give better lifetime as ion-transport layers can degrade as often problematic in a battery. Because electrons have the best mobility, the semiconductor is grown n-type so that it is the electrons which are transported further to the top contact in the most efficient manner, and the holes are extracted in the shortest possible distance. The depletion length which is the region over which the high field drops to small values, depends on the semiconductor doping level and can be on the order of 100-1000 nm. This is designed to match the absorption length of resonantly-tuned light within the semiconductor, so that the maximum energy is extracted. The semiconductor can be grown in a variety of ways. For instance we have grown n-type CdTe using electrochemical deposition, which can be cheap and scaled up—the Damascene Cu process is already used within the semiconductor industry. Similarly we have electrochemically grown ZnO and PbTe semiconductors, which have different band gaps, thus allowing control over which colours of light can be absorbed. In some embodiments, the depletion length can be on the order of 30-2000 nm.

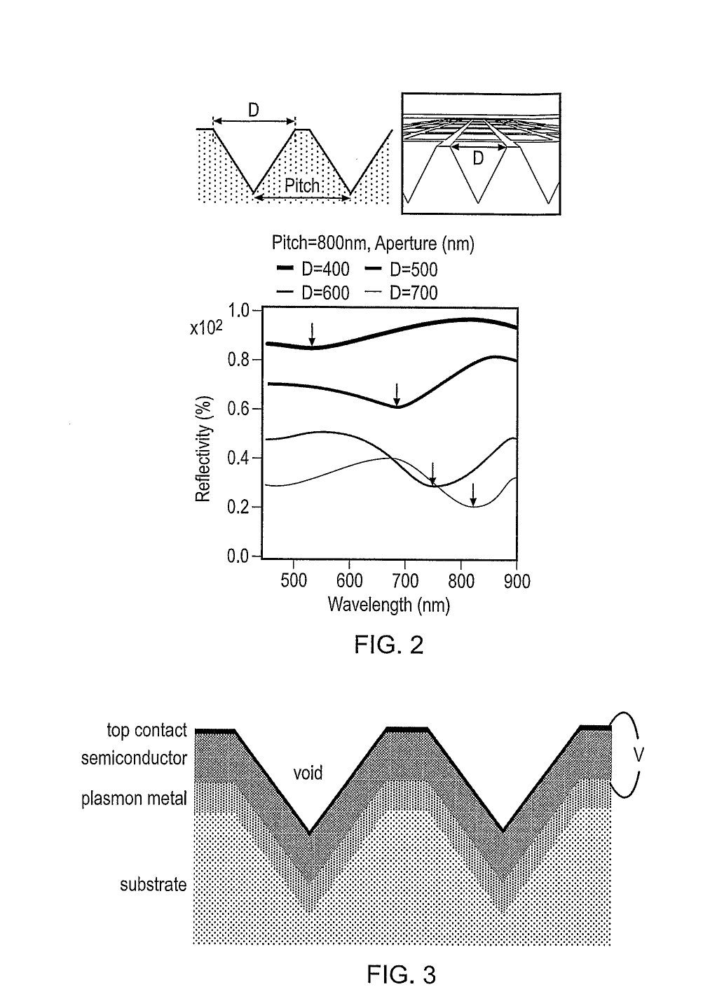

The metallic voids support localized plasmons (that we have detailed previously and produced a number of papers on [1-5]). The inventive step of this patent is to use the localised plasmons to produce optical field in the high electric field region near the metal surface. The plasmons can be tuned by changing the structural void shape and size—we have shown results for spherical voids and pyramidal pits. For instance in the case of pyramidal pits, increasing the square aperture size from 400 nm to 700 nm, tunes the mode across the entire visible spectrum (FIG. 2). Most important is the average optical intensity in the high field Schottky region. The enhancement spectrum is similar to the absorption spectrum and this shows that the field near the metal surface is enhanced by the plasmons. Absorption of nearly 100% is possible, implying that similar absorption magnitudes can be obtained in a semiconductor grown inside the void, for a solar cell device.

One realisation of the metallic void photovoltaic cell is shown in FIG. 3. We envisage patterning a substrate initially through a low-cost process, such as reel-to-reel embossing of the pits into a plastic that can be cured. Then a thin (eg. 30 nm) metal film (the metal should be plasmon active so Au, Ag, Cu are the best examples) is deposited in the pits, for example by electro-less chemical deposition or vacuum sputtering. Contact is made to this layer, and it is used in an electrochemical cell to deposit the doped semiconductor of choice to a thickness of 100-1000 nm. Finally a top contact is added (for instance also by electrochemical deposition) and treated (for instance by an annealing step) in such a way as to give an ohmic contact to the semiconductor. The top contact can be very thin (to let light pass through), or can be transparent (eg. Indium Tin Oxide or similar) or it can be patterned so that it is absent in the pits. In some embodiments, the doped semiconductor of choice is deposited to a thickness of 20-2000 nm.

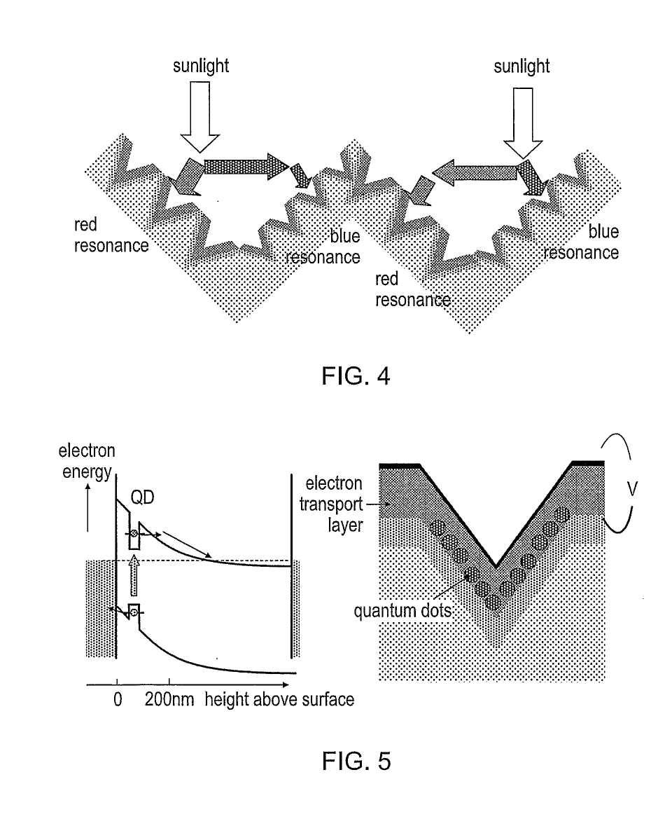

As shown earlier the plasmons have relatively broad resonances. These are helpful to provide an efficient match to the solar spectrum, avoiding a problem found in many photovoltaic cells that absorption of light with an energy much greater than the bandgap of the semiconductor harnesses only a fraction of the photon energy (the excess energy above the bandgap is given out as heat). By folding the plasmon void surface (eg. FIG. 4) and making opposite faces of it out of different sized voids with different semiconductors grown on top, faces of the photovoltaic cell either absorb efficiently or reflect efficiently any non-absorbed colours to opposite faces of the cell which can absorb them. It should be possible to produce such composite cells at relatively low cost using appropriate master embossing and angled deposition.

Because flexible plastic substrates could potentially be used (providing the semiconductor layer is not too thick), the resulting cells in thin film form could be conformally wrapped around any object or surface. The advantage of using an inorganic semiconductor is that the lifetime greatly exceeds that of any organic semiconductor. Organics however possibly have other advantages of flexibility and low cost growth (eg. spin-on deposition).

We can also envisage enhancing the performance by embedding absorbing active species in the high field region near the metal void surface. Similar ideas for the Grätzel cell use Ruthenium dyes on TiO₂ substrate, however these dyes are expensive and their lifetime is unclear. As well as this approach, we can use semiconductor nanoparticles (called quantum dots, QDs) which can be used to coat the metal surface before growth of the top semiconducting layer. Different sized QDs have different bandgaps allowing easy tuning of the absorption spectrum (for instance by combining mixtures of QDs). The electron and hole pairs produced in the quantum dot can tunnel rapidly out (before they can recombine) as long as it is placed in the high field region of the device (FIG. 5). It would thus be easy to match QDs to different plasmon resonances to provide efficient faces of the cell. The QDs appear to have long lifetimes, and can be independently optimised to the properties of the electron-transporting semiconductor layer. Sufficient QD thickness would have to be used to provide strong absorption, but this is aided by the plasmon void optical field distribution.

According to an embodiment of the invention, a DC surface field associated with the Schottky region can be less than 10⁷ Vm⁻¹ in strength and larger than 100 nm in dimension. The field strength and the extent of the field can be selected according to the type and doping level of the semiconductor.

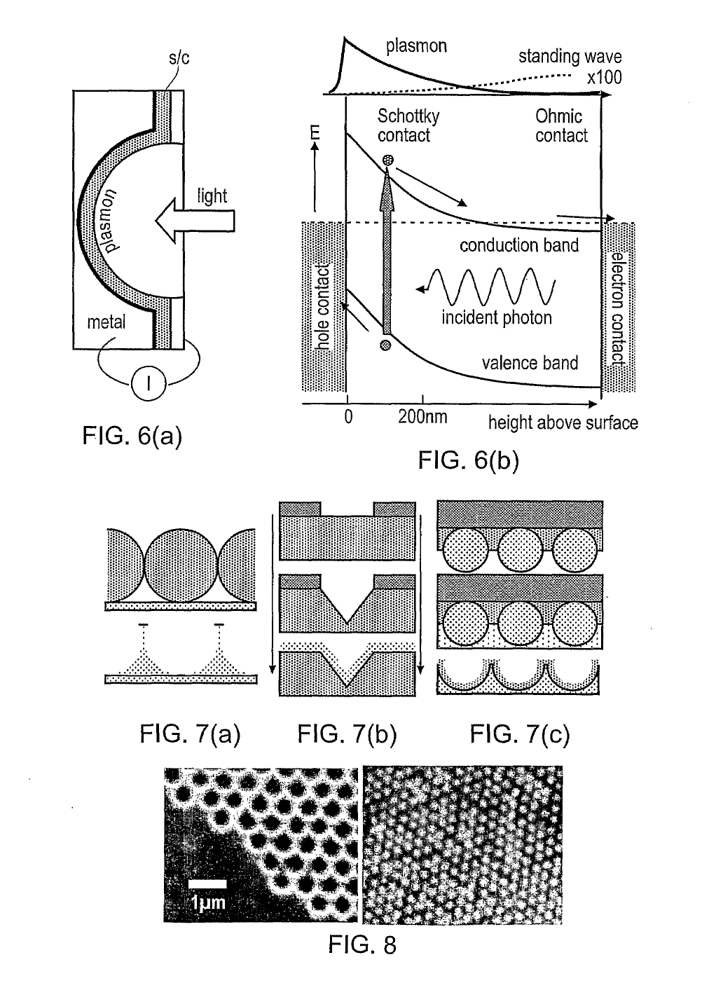

FIG. 6(a) shows a photovoltaic device having a void that is substantially spherical. FIG. 6(b) schematically shows the band gap alignment and plasmon mode overlap for the embodiment device shown in FIG. 6(a). In some embodiments (such as that shown in FIG. 6(a)), the voids can comprise substantially spherical spheres that are truncated to allow free entry of light.

As described herein, the size of the voids provided in accordance with embodiments of this invention can be varied to tune the modes of plasmons that can be confined therein. Accordingly, the modes can be chosen to correspond to the excitation energies of electron-hole pairs within the Schottky region. In the example shown in FIG. 6(a), the void has a radius of 250 nm.

As described herein, the confinement of plasmons enhances the optical field in the proximity of the semiconductor that coats the metallic surface within each void. Accordingly, the absorption strength within the semiconductor is increased. In turn, this means that relatively thin layers of semiconductor can be used. Since the semiconductor layer is thin, holes created in the Schottky region are created in close proximity to the metallic surface. This allows for efficient collection and extraction of the holes. This is a significant benefit, since hole transport is a key problem in known photovoltaic devices.

FIG. 7 illustrates a number of examples of fabrication methods according to embodiments of the invention. Each example allows depth, the lateral size, the spacing and metal composition of the voids to be controlled.

In FIG. 7(a), a plurality of spheres 10 such as latex spheres are arranged on a substrate 12 to form an array corresponding to the desired array of voids in a photovoltaic device. The size of the spheres can be chosen according to the dimensions of the voids that are to be produced. For example, the spheres can have diameters in the range 50-5000 nm.

Metal is then deposited around the spheres (for example using electrochemical deposition), and the spheres are subsequently removed (e.g. dissolved) to expose a metallic surface forming a plurality of voids. The metallic surface can then be coated with a semiconductor and a top contact can be provided. The amount of metal that is deposited can be selected according to the deepness of the voids that are to be produced.

In the example shown in FIG. 7(b), the anisotropic etching of apertures on silicon with Potassium Hydroxide (KOH) is exploited to produce voids with atomically-smooth steep sidewalls. The walls are then sputter-coated with suitable metals.

The example fabrication method illustrated in FIG. 7(c) includes stamping and embossing flexible films. Trials using Polydimethylsiloxane (PDMS) have proved to produce excellent substrates comprising voids suitable for metal coatings that support plasmons. FIG. 8 shows an example of PDMS stamped Au-coated hemi-spherical voids.

In accordance with an embodiment of the invention, the photovoltaic device can be specifically tuned for efficient operation in the solar spectrum. Although the use of plasmon confining voids can produce devices that are highly efficient at specific wavelengths, for wavelengths outside the localised plasmon resonance, the surface of the device is typically reflective. Accordingly, incident light that does not correspond to a plasmon resonance within the voids cannot contribute to the performance of the device as a photovoltaic cell.

According to an embodiment of the invention, a photovoltaic device in which the metallic surface is folded to form a plurality of opposing faces. An example of this is discussed above in relation to FIG. 4. As described herein, the voids in the opposing faces can be tuned to receive light of a different wavelength. In one embodiment, the voids in a first set of faces can be tuned to absorb a first wavelength spectrum and reflect a second wavelength spectrum. The voids in a second set of faces (that oppose the first set of faces) can be tuned to absorb in the second wavelength spectrum and reflect in the first wavelength spectrum. In this way, each set of faces can cooperate to absorb light that has been reflected by the other set of faces, thereby improving the overall efficiency of the device.

Accordingly there has been described a photovoltaic device and a method of making the photovoltaic device. The device includes a metallic surface defining a plurality of voids for confining surface plasmons. The metallic surface is coated with a semiconductor to form a Schottky region at an interface between the metallic surface and the semiconductor within each void.

### REFERENCES

The contents of the references are incorporated herein in the entirety.
[1] “Confined Plasmons in Metallic Nanocavities”, S. Coyle, M. C. Netti, J. J. Baumberg, M. A Ghanem, P. R. Birkin, P. N. Bartlett, D. M. Whittaker, Phys. Rev. Lett. 87, 176801 (2001)
[2] “Compact Strain-Sensitive Flexible Photonic Crystals for Sensors”, Otto L. J. Pursianinen, Jeremy J. Baumberg, Kevin Ryan, Holger Winkler, Benjamin Viel and Tilmann Ruhl, Appl. Phys. Lett. 87, 101902 (2005)
[3] “Tunable Resonant Optical MicroCavities by Templated Self-Assembly”, G V Prakash, L Besombles, J J Baumberg, M Abdelsalam, P N Bartlett, Opt. Lett 29, 1500 (2004).
[4] “Tuning localized plasmons in nanostructured substrates for surface-enhanced Raman scattering”, Nicholas M. B. Perney, Jeremy J. Baumberg, Majd E. Zoorob, Martin D. B. Charlton, Sven Mahnkopf, Caterina M. Netti, Optics Express, 14, 847 (2006)
[5] “Plasmonic bandgaps and Trapped Plasmons on Nanostructured Metal Surfaces”, T. A. Kelf, Y. Sugawara, J. J. Baumberg, M. Abdelsalam and P. N. Bartlett, Phys Rev. Lett. 95 116802 (2005)

1. A photovoltaic device comprising a metallic surface defining a plurality of voids for confining surface plasmons, wherein the metallic surface is coated with a semiconductor to form a Schottky region at an interface between the metallic surface and the semiconductor within each void.

2. The photovoltaic device of claim 1, wherein the voids comprise pyramidal pits.

3. The photovoltaic device of claim 2, wherein a square aperture of the pyramidal pits is in the range 400-2000 nm.

4. The photovoltaic device of claim 3, wherein a square aperture of the pyramidal pits is in the range 400-700 nm.

5. The photovoltaic device of claim 1, wherein the voids are substantially spherical in shape.

6. The photovoltaic device of claim 1 comprising an ohmic top contact on the semiconductor.

7. The photovoltaic device of claim 1, wherein the semiconductor is an n-type semiconductor.

8. The photovoltaic device of claim 7, wherein the semiconductor comprises CdTe, ZnO or PbTe.

9. The photovoltaic device of claim 1, wherein the semiconductor is a p-type semiconductor

10. The photovoltaic device of claim 9, wherein the semiconductor comprises GaAs or InAs.

11. The photovoltaic device of claim 7, wherein the semiconductor comprises and alloy or heterostructure.

12. The photovoltaic device of claim 1, wherein the metallic surface is defined by a thin film metallic layer on a substrate.

13. The photovoltaic device of claim 1, wherein a depletion length of the Schottky region matches an absorption length of light that is resonantly tuned to a bandgap of the semiconductor.

14. The photovoltaic device of claim 13, wherein the depletion length is in the range 100-1000 nm.

15. The photovoltaic device of claim 13, wherein the depletion length is in the range 30-2000 nm.

16. The photovoltaic device of claim 1, wherein the metallic surface is folded to form a plurality of opposing faces.

17. The photovoltaic device of claim 16, wherein the voids defined in at least one of said faces are larger than the voids defined in at least one other face.

18. The photovoltaic device of claim 16, wherein the metallic surface defining the voids in at least one of said faces is coated with a different semiconductor to the metallic surface defining the voids in at least one other of said faces.

19. The photovoltaic device of claim 1 comprising a plurality of quantum dots on the metallic surface.

20. A solar cell comprising the photovoltaic device of claim 1.

21. A method of making a photovoltaic device, the method comprising: forming a metallic surface to define a plurality of voids for confining surface plasmons; and coating the metallic surface with a semiconductor to form a Schottky region at an interface between the metallic surface and the semiconductor within each void.

22-31. (canceled)
